(19) United States
(12) Patent Application Publication
(10) Pub. No.: US 2018/0130679 A1
(43) Pub. Date: May 10, 2018

(54) PLASMA PROCESSING DEVICE

(71) Applicant: INDUSTRIAL TECHNOLOGY RESEARCH INSTITUTE, HSIN-CHU (TW)

(72) Inventors: CHIH-CHIANG WENG, Taoyuan (TW); CHEN-DER TSAI, Hsinchu County (TW); CHIA-JEN TING, Hsinchu County (TW); YING-FANG CHANG, Hsinchu (TW)

(21) Appl. No.: 15/392,381

(22) Filed: Dec. 28, 2016

(30) Foreign Application Priority Data
Nov. 8, 2016 (TW) 105136324

(51) Int. Cl. H01L 21/67; H01L 21/687; H01L 21/02; H01J 37/32

(52) U.S. Cl. CPC H01L 21/67069; H01L 21/68714; H01L 21/02236; H01L 29/1608; H01J 37/32009; H01J 37/3244; H01J 37/32532; H01L 21/02252

(57) ABSTRACT

The present invention relates to a plasma processing device, comprising: an upper electrode has a plurality of protruding posts which made by conducting material and protruded out of one surface of the upper electrode and connected to a plasma producing source and formed a plurality of circles that around a center, each circle has at least one protruding post, the surface of the upper electrode that has protruding posts is covered with dielectric material, a plurality of gas holes disposed between protruding posts and connected to working gas source; a rotatable lower electrode is made of conducting material and covered with dielectric material which has a carry surface facing the surface of the upper electrode that has protruding posts for carrying workpiece.

### CROSS REFERENCE TO RELATED APPLICATION

This application also claims priority to Taiwan Patent Application No. 105136324 filed in the Taiwan Patent Office on Nov. 8, 2016, the entire content of which is incorporated herein by reference.

### TECHNICAL FIELD

The present disclosure relates to a plasma processing device, and more particularly, to a plasma processing device with improved design in plasma electrode distribution, electrode arcing protection and rotary carrier that is provided for large-area plasma oxide etching system.

### BACKGROUND

Plasma processing is a type of dry process whereas the referred plasma can include charged particles, such as electron, ions, etc., and uncharged particles in metastable state, free-radicals, light and heat, and so on. As the plasma processing can create a specific physical and chemical reaction environment, it can be applied in various applications. For instance, in the optoelectronic semiconductor manufacturing process, low pressure (or vacuum) plasma system is commonly used for surface modification, etching, and film deposition. Nowadays, with the rapid development of power source system, the generation of plasma at an atmospheric pressure environment is becoming achievable. That is, a plasma can be generate under an atmospheric pressure without using any expensive vacuum chamber, or vacuuming devices, and therefore, the equipment cost for generating plasma can reduced significantly comparing to those vacuum plasma systems. Moreover, since operationally the application of atmospheric plasma is no longer restricted by the size of vacuum chamber, the atmospheric plasma means can be expanded easily and used in any continuous manufacturing process which means that the applicability of the atmospheric plasma process is widened significantly. Currently, the applications of atmospheric plasma include the decomposition of waste organic gases, the surface activation for solid substrate, etching and cleaning processes, film deposition process, water resource treatment, and biomedical applications, etc.

Nowadays, the most commonly used SiC wafer polishing process being adopted worldwide is still the conventional silicon wafer polish method, in which the level of polishing on the SiC wafer is adjusted only through the adjustment to the liquid polish agent and the calibration to the corresponding manufacturing process. Consequently, such conventional silicon wafer polish process can be a time consuming and highly contaminated process. Correspondingly in a leading research team in Osaka University, Japan, an assisted polishing process for enabling surface oxidation on SiC wafer by the use of RF atmospheric plasma is being developed. However, since the plasma power being generated is comparatively small and can only being used for single-point modification that it is difficult to be used in any large-area processing and can only produce an oxidation layer at 3 nm/min, such RF atmospheric plasma process is questionable to be used any mass production process.

Therefore, it is in need of a plasma processing device with improved design in plasma electrode distribution, electrode arcing protection and rotary carrier that is provided for large-area plasma oxide etching system.

### SUMMARY

In an embodiment, the present disclosure provides a plasma processing device, comprising:

an upper electrode, further comprising:
a plurality of protruding posts, each made of a conducting material, and being arranged protruding out of one surface of the upper electrode and connected to a plasma power source while allowing the plural protruding posts to be distributed forming a plurality of circles surrounding a center in a manner that each circle includes at least one of the plural protruding posts, and enabling the surface of the upper electrode with the plural protruding posts to be covered by a dielectric material; and
a plurality of gas holes, disposed between the plural protruding posts and connected to a working gas source; and
a rotatable lower electrode, made of a conducting material, being covered by a dielectric material while formed with a carrying surface for carrying a workpiece in a manner that the carrying surface is oriented facing toward the surface of the upper electrode that is arranged with the plural protruding posts.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a front view of a plasma processing device according to an embodiment of the present disclosure.

FIG. 2 is a three-dimensional view of an upper electrode and a lower electrode used in an embodiment of the present disclosure.

FIG. 3 is an A-A sectional view of FIG. 2.

FIG. 4 is schematic diagram showing the cooling channel used in an embodiment of the present disclosure.

FIG. 5 is schematic diagram showing a distribution of the plural protruding posts used in an embodiment of the present disclosure.

FIG. 6 is schematic diagram showing the plural protruding posts of FIG. 5 to be distributed forming a plurality of circles surrounding a center as the protruding posts rotate.

FIG. 7 is schematic diagram showing another distribution of the plural protruding posts used in another embodiment of the present disclosure.

FIG. 8 is a B-B sectional view of FIG. 2.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

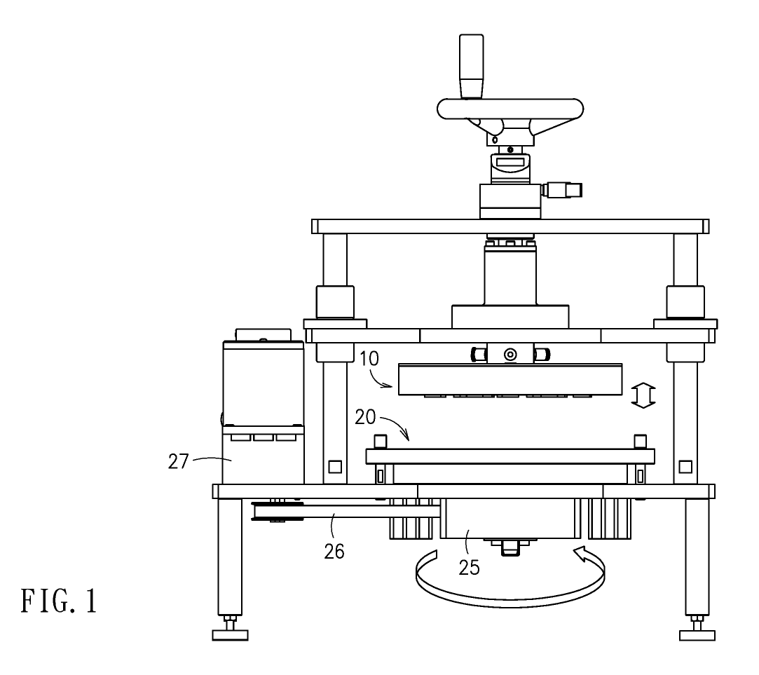

Please refer to FIG. 1, which is a front view of a plasma processing device according to an embodiment of the present disclosure. As shown in FIG. 1, the plasma processing device comprises: an upper electrode 10 and a rotary lower electrode 20 that is grounded. In this embodiment, the upper electrode 10 is disposed for allowing the same to move up and down, i.e. it can be move toward or away from the lower electrode 20. The upper electrode 10 is used for providing processing gases and used as an output electrode of a plasma power source, while the lower electrode 20 is used as a carrier for carrying a workpiece 30 and also as a ground electrode of a plasma power source. Moreover, the area spaced between the upper electrode 10 and the lower electrode 20 is the area where plasma is generated.

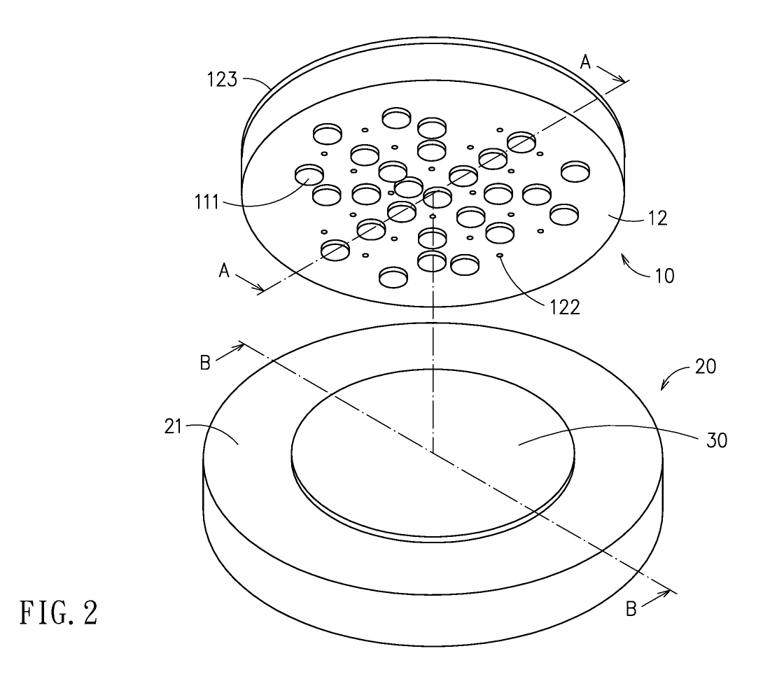

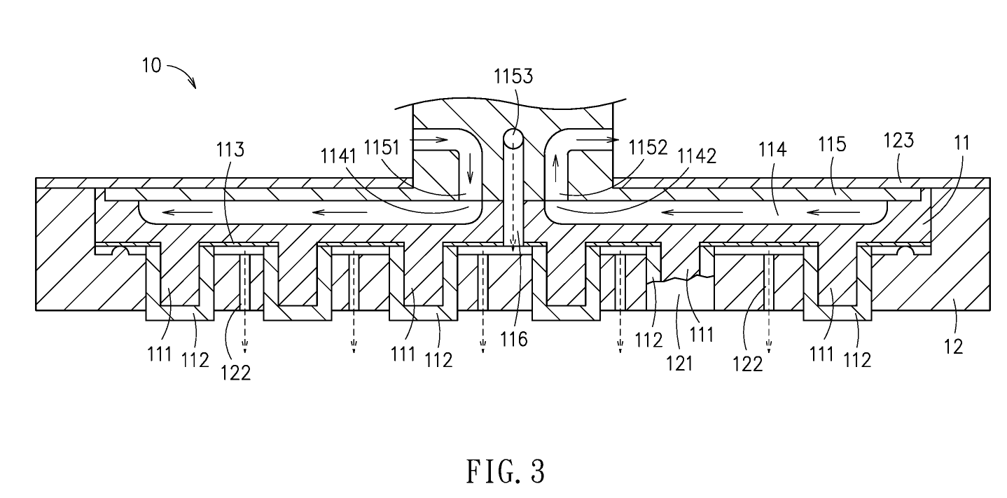

FIG. 2 is a three-dimensional view of an upper electrode and a lower electrode used in an embodiment of the present disclosure, and FIG. 3 is an A-A sectional view of FIG. 2. As shown in FIG. 2 and FIG. 3, the upper electrode 10 further comprises: a base 11 made of a conducting material; and a shell 12 made of a dielectric material. In this embodiment, there are a plurality of protruding posts 111 disposed on a surface of the base 11, i.e. the bottom of the base 11 in FIG. 2, whereas each of the plural protruding posts 111 is connected to the plasma power source. It is noted that since the plural protruding posts 111 are connected to the base 11, the plasma power source can first be connected to the base 11, and thereby connected to the plural protruding posts 111. In another word, the plural protruding posts 111 can be connected to the plasma power source directly or indirectly according to actual requirement. In addition, each of the plural protruding posts 111 is a column that is arranged for enabling its axial end to face toward the lower electrode 20; and each of the plural protruding posts 111 is enclosed by a corresponding sleeve 112 that is made of a dielectric material. Moreover, the shell 12 is formed with a plurality of first holes 121 at positions corresponding to the plural protruding posts 111 while being provided for allowing the base 11 to be disposed inside the shell 12 and the plural protruding posts 111 that are enclosed by the plural sleeves 121 to protrude out the shell 12 via the corresponding first holes 121. In this embodiment, there are a plurality of air holes 122 formed at positions between the plural protruding posts 111, whereas there is a dielectric spacer 113 disposed on the base 11 at a surface thereof where the plural protruding posts 111 are disposed. It is noted that the spacer 113 can be a ceramic piece or a Teflon piece. Furthermore, the base 11 is formed with a cooling channel 114 and a first gas inlet 116 at a surface thereof that is opposite to the surface having the plural protruding posts 11 disposed, i.e. the cooling channel 114 and the first gas inlet 116 are formed on the top surface of the base 11.

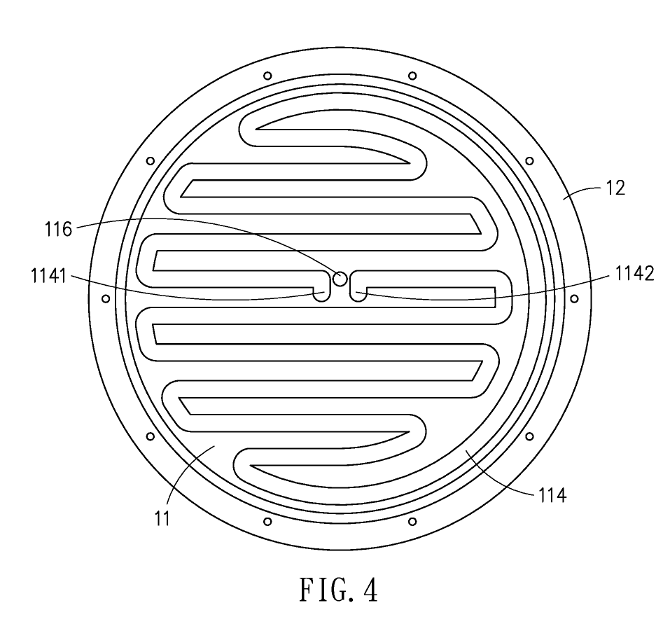

As shown in FIG. 3 and FIG. 4, the cooling channel 114 is continuous channel that is formed with an entrance 1141 and an exit 1142. In this embodiment, the base 11 has a first cover panel 115 that is made of a conducting material and disposed on the base 11 at a surface thereof opposite to the surface having the plural protruding posts 111 disposed while covering the cooling channel 114. In addition, the first cover panel 115 is formed with a flow inlet 1151, a flow outlet 1152 and a second gas inlet 1153 in a manner that a cooling fluid can be guided to flow into the entrance 1141 via the flow inlet 1151 and out of the exit 1142 into the flow outlet 1152. Moreover, a process gas can be guided to flow through the second gas inlet 1153, the first gas inlet 116 and then out of the shell 12 via the plural air holes 122 toward the plasma generation area defined between the upper electrode 10 and the lower electrode 20. In this embodiment, the shell 12 further has a second cover panel 123 that is made of a dielectric material and is disposed on the shell 12 at a surface thereof opposite to the surface having the plural protruding posts 111 disposed while covering the first cover panel 115. When the first cover panel 115 is engaged and married to the base 11 and the second cover panel 123 is also engaged and married to the shell 12, the shell 12 is ready to mate with the base 11 like a sandwich where the base 11 is sandwiched between the second cover panel 123 and the shell 12 for sealing the cooling channel 114. It is noted that the cooling fluid flowing inside the cooling channel 114 is used for cooling the upper electrode 10 for maintaining the temperature thereof at a specific temperature.

The reason why the shell 12, the sleeves 112 and the spacer 113 are all made of a dielectric material is to prevent the charged particles that are generated by each of the exciting protruding posts from bombarding directly on the conducting electrode for causing the same to be damaged by arc discharging. However, there can be other means to be adopted in the present disclosure for preventing the aforesaid damage. For instance, the shell 12 and the sleeves 112 can be integrally formed from a dielectric material into a one-piece unit that is arranged covering on the upper electrode 10 and the protruding posts 111.

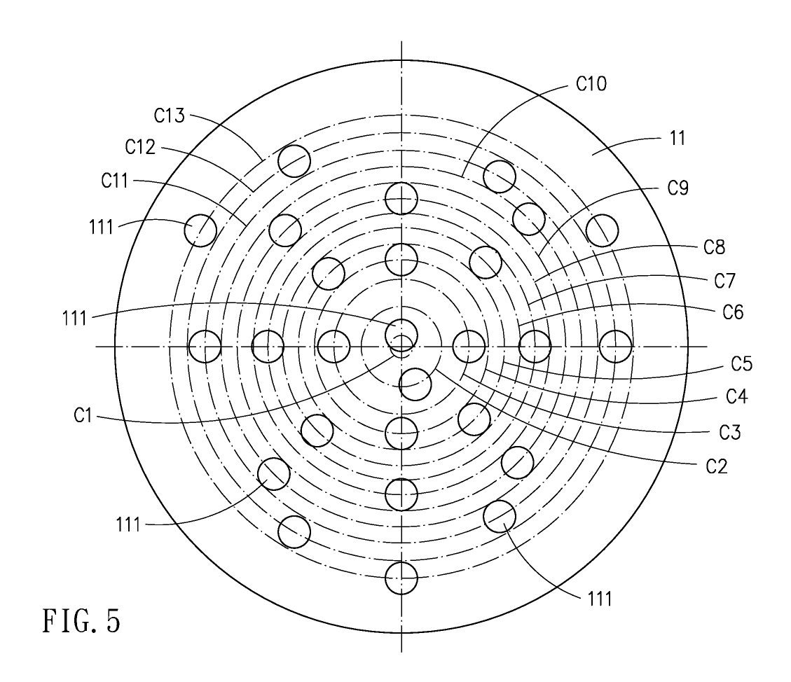

Please refer to FIG. 5, which is schematic diagram showing a distribution of the plural protruding posts used in an embodiment of the present disclosure. In FIG. 5, the plural protruding posts 111 are featured by their distribution, that the protruding posts 111 are distributed forming a plurality of circles C1˜C13 surrounding a center in a manner that each circle C1˜C13 includes at least one of the plural protruding posts 111. In the embodiment shown in FIG. 5, the base 11 is a circular-shape object and thus the thirteen circles C1˜C13 are arranged surrounding the center of the base 11. However, if the base 11 is not circular, any point of the base 11 can be selected and used as the center. In FIG. 5, each of the first circle C1 and the second circle C2 is formed by the definition of one protruding post 111, each of the third to the tenth circles (C3˜C10) is formed by the definition of two protruding posts 111, and each of the eleventh to the thirteenth circles (C11˜C13) is formed by the definition of three protruding posts 111. In addition, in this embodiment, each of the protruding posts 111 is formed with the same diameter, but it is not limited thereby and thus they can be formed with different diameters. Moreover, there is at least one air hole 122 to be formed at a position between any two neighboring circles C1˜C13 or on each circle C1˜C13.

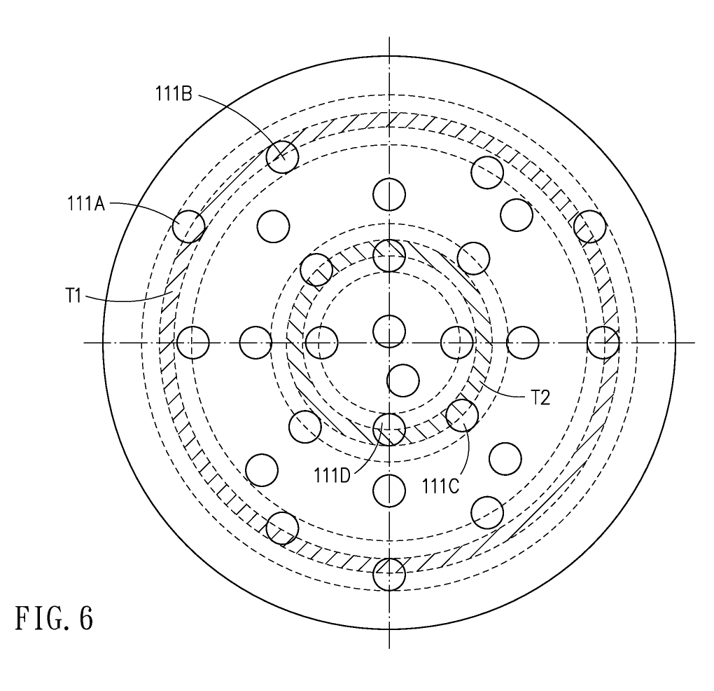

In FIG. 6, another characteristic of the present disclosure is revealed, that is, the plural protruding posts are distributed forming a plurality of circles surrounding a center in a manner that there are circular rim areas to be formed by the enclosure between the outer tangent circle and inner tangent circle to the protruding posts of the same circle, and the outer rim of one circular rim area of one protruding post in one circle is arranged at least tangent to the inner rim of its neighboring protruding post in another circle. In other words, circular rim areas are formed by the outer tangent circle and inner tangent circle to the protruding posts of the same circle, and the protruding posts are arranged in a manner that the outer rim of one circular rim area of one protruding post overlaps to at least tangent to the inner rim of its neighboring protruding post in another circle. As shown in FIG. 6, the two circular rim areas relating to the two neighboring protruding posts 111A and 111B are partially overlapped with each other (i.e., share an overlapped area T1), while another two circular rim areas relating to the two neighboring protruding posts 111C and 111D also share an overlapped area T2, whereas similarly, all the other pair of neighboring circular rim areas are partially overlapped with each other and consequently a circular coverage area can be formed from the all the circular rim areas. It is noted that the circular coverage area should cover all the process area of the workpiece 30, as shown in FIG. 2. However, the overlapping between two neighboring circular rim areas is not necessary, only if the outer rim of one circular rim area of one protruding post in one circle is arranged at least tangent to the inner rim of its neighboring protruding post in another circle.

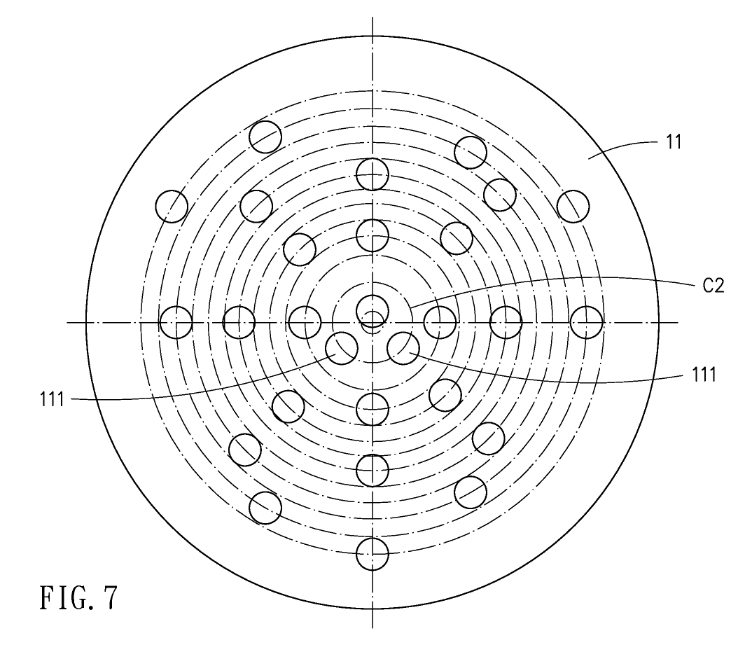

Please refer to FIG. 7, which is schematic diagram showing another distribution of the plural protruding posts used in another embodiment of the present disclosure. The embodiment shown in FIG. 7 is similar to the one shown in FIG. 5, but is different in that: the second circle C2 of FIG. 7 is defined by two protruding posts 111 instead of one in FIG. 5. As indicated in the embodiments shown in FIG. 5 and FIG. 7, each of the circles should be defined by at least one protruding posts, whereas the number of the protruding posts can be determined according to actual requirement.

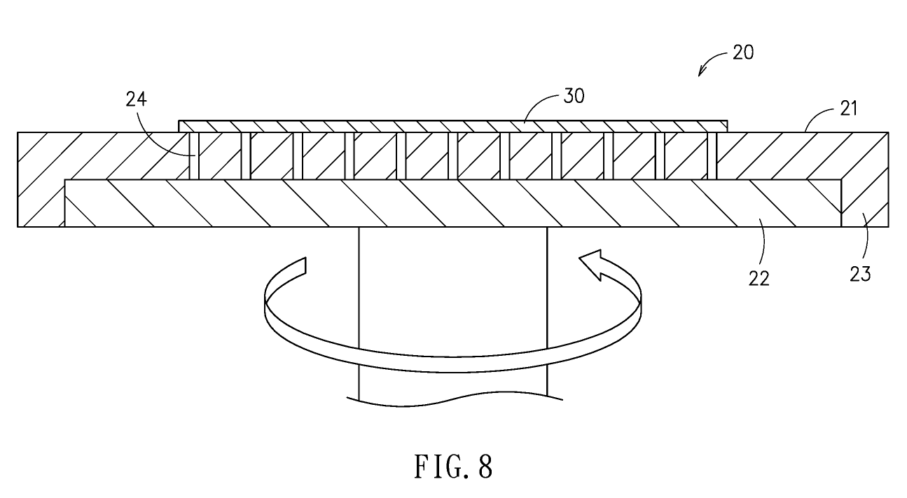

As shown in FIG. 2 and FIG. 8, the lower electrode 20 is formed with a carrying surface 21 for carrying the workpiece 30, and the surface of the carrying surface 21 that is arranged facing toward the upper electrode 10 is provided for the plural protruding posts 111 to be disposed thereat. In this embodiment, the lower electrode 20 comprises: an inner part 22 that is grounded and is made of a conducting material; and an outer part 23 that is made of a dielectric material and is arranged covering on the surface of the inner part 22. The lower electrode 20 is arranged for allowing the same to be driven to rotate. As shown in FIG. 1, the rotary shaft 25 of the lower electrode 20 is engaged to a timing belt pulley 26 and a power source 27, such as a motor, by that the lower electrode 20 can driven to rotate in an adjustable rotating speed. Nonetheless, the driven mechanism for the lower electrode 20 is not limited thereby. In this embodiment, since the lower electrode 20 is a circular-shaped object, the rotation center of the lower electrode 20 and the center of the upper electrode 10 are concentric. Moreover, there are a plurality of venting holes 24 that are formed on the carrying surface 21 of the lower electrode 20 to be used for attracting and positioning the workpiece 30 on the carrying surface 21.

As shown in FIG. 2, the disposition of the protruding posts 111 on the upper electrode 10 can facilitate the plasma to be excited at the positions where the protruding posts 111 are located, and by the well-planned distribution design for the plural protruding posts 111 and the rotary mechanism for the lower electrode 20, plasma can be generated to cover the whole area needed to be processed on a workpiece.

To sum up, the present disclosure provides an upper electrode with non-symmetrically distributed protruding posts and a rotary lower electrode, whereas the upper electrode is further formed with a plurality of air holes for guiding a process gas to inflow. Operationally, when a plasma is excited to be generated within an area defined between the upper electrode and the lower electrode, and when the lower electrode is being driven to rotate, plasma can be generated to cover the whole area needed to be processed on a workpiece by the well-planned distribution design for the plural protruding posts.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A plasma processing device, comprising:
an upper electrode, further comprising:
a plurality of protruding posts, each made of a conducting material, and being arranged protruding out of one surface of the upper electrode and connected to a plasma power source while allowing the plural protruding posts to be distributed forming a plurality of circles surrounding a center in a manner that each circle includes at least one of the plural protruding posts, and enabling the surface of the upper electrode with the plural protruding posts to be covered by a dielectric material; and
a plurality of gas holes, disposed between the plural protruding posts and connected to a working gas source; and
a rotatable lower electrode being grounded, made of a conducting material, being covered by a dielectric material while formed with a carrying surface for carrying a workpiece in a manner that the carrying surface is oriented facing toward the surface of the upper electrode that is arranged with the plural protruding posts.

2. The plasma processing device of claim 1, wherein there are circular rim areas to be formed by the enclosure between the outer tangent circle and inner tangent circle to the protruding posts of the same circle, and the outer rim of one circular rim area of one protruding post in one circle is arranged at least tangent to the inner rim of its neighboring protruding post in another circle.

3. The plasma processing device of claim 1, wherein each of the plural protruding posts is a column that is arranged for enabling its axial end to face toward the lower electrode.

4. The plasma processing device of claim 3, wherein the plural protruding posts are formed with at least one diameter size.

5. The plasma processing device of claim 1, wherein there is at least one air hole to be formed at a position between any two neighboring circles or on each circle.

6. The plasma processing device of claim 5, wherein the upper electrode further comprises:
a base, made of a conducting material while being provided for allowing the plural protruding posts to be disposed on a surface thereof;
a plurality of sleeves, made of a dielectric material while each being disposed enclosing one of the plural protruding posts corresponding thereto; and
a shell, formed with the plural air holes, made of a dielectric material, and having a plurality of first holes formed at positions corresponding to the plural protruding posts while being provided for allowing the base to be disposed inside the shell and the plural protruding posts plural protruding posts that are enclosed by the plural sleeves to protrude out of the shell via the corresponding first holes.

7. The plasma processing device of claim 6, wherein the base further comprises:
a cooling channel with an entrance and an exit, disposed on the base at a surface thereof opposite to the surface having the plural protruding posts disposed; and
a first cover panel, made of a conducting material, disposed on the base at a surface thereof opposite to the surface having the plural protruding posts disposed while covering the cooling channel, and further having a flow inlet and a flow outlet formed thereat for allowing a cooling fluid to flow into the entrance of the cooling channel via the flow inlet and out of the exit of the cooling channel into the flow outlet.

8. The plasma processing device of claim 7, wherein the shell further comprises:
a second cover panel, made of a dielectric material, disposed on the shell at a surface thereof opposite to the surface having the plural protruding posts disposed while covering the first cover panel.

9. The plasma processing device of claim 6, wherein the base further comprises:
a spacer, made of a dielectric material, disposed on the base at a surface thereof where the plural protruding posts are disposed.

10. The plasma processing device of claim 1, further comprising:
a plurality of venting holes, formed on the carrying surface of the rotary lower electrode to be used for attracting and positioning the workpiece on the carrying surface.
